(19) United States
(12) Patent Application Publication
(10) Pub. No.: US 2009/0156002 A1
(43) Pub. Date: Jun. 18, 2009

(54) MANUFACTURING METHOD FOR SEMICONDUCTOR DEVICE AND MANUFACTURING APPARATUS FOR SEMICONDUCTOR DEVICE

(76) Inventors: Keiji Fujita, Oita (JP); Hisashi Kaneko, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/331,199

(22) Filed: Dec. 9, 2008

(30) Foreign Application Priority Data
Dec. 10, 2007 (JP) 2007-318267

(51) Int. Cl. H01L 21/443; C23C 16/44

(52) U.S. Cl. 438/680; 204/155; 257/E21.478

(57) ABSTRACT

A wafer is placed on a lower electrode disposed in a reaction chamber; process gas is introduced into the reaction chamber; a magnetic field is applied at a position spaced from a surface of the wafer to be processed; plasma is generated by applying a high-frequency voltage between the lower electrode and an upper electrode disposed to face the lower electrode; the magnetic field is removed after the plasma is stabilized; and the wafer is plasma-processed.

### CROSS-REFERENCE TO RELATED APPLICATION

This application is based upon and claims the benefit of priority from the prior Japanese Patent Application No. 2007-318267 filed on Dec. 10, 2007, the entire contents of which are incorporated herein by reference.

### BACKGROUND OF THE INVENTION

The present invention relates to a manufacturing method and a manufacturing apparatus for semiconductor device using plasma process such as parallel-plate plasma CVD (Chemical Vapor Deposition).

Generally, a parallel-plate plasma processing apparatus is used in film formation or etching process of a manufacturing process for semiconductor device. The parallel-plate plasma processing apparatus is for generating plasma for wafer process by applying high frequency between two electrodes disposed to face each other in a vacuum chamber and by flowing process gas such as film formation gas and etching gas.

In such a parallel-plate plasma processing apparatus, if spatial non-uniformity of a potential, electronic density and electronic temperature of generated plasma exists on a wafer to be processed, an equilibrium state of an electronic temperature and an ion current invading into a wafer from plasma is locally collapsed, resulting in charge-up. At this time, for example, charges are stored in an electrode of a transistor previously formed on a wafer to apply a high electric field to a gate insulation film, resulting in flow of tunnel current and thus the gate insulation film may be deteriorated. In the worst case, the gate insulation film may be destructed. There is a problem of performance degradation of transistor or product yield degradation caused by plasma damage such as that of the gate insulation film.

In recent years, with further miniaturization of semiconductor devices, thinning of a transistor gate insulation film has been accelerated for higher performance thereof. Acceleration of thinning of the gate insulation film causes more influence of plasma distribution on the gate insulation film, which makes the problem of plasma damage significant.

Meanwhile, plasma CVD has been used, for example, in a film formation process of a low dielectric constant film used to improve device performance. Since film formation process is repeated for many times in order to form interlayer insulation films of a laminated structure, plasma damage is increased. When plasma process is performed to remove oxide on Cu interconnect in order to improve reliability of the interconnect or to form a plasma CVD film on a Cu interconnect, the Cu interconnect is charged and then a transistor gate is charged, whereby a problem becomes more significant.

In some cases, a process condition may be changed purposely during film formation by plasma CVD in order to change film quality at the middle of film formation process. In this case also, plasma distribution becomes non-uniform, thereby causing a problem that plasma damage is increased.

To improve uniformity in plasma etching, Japanese Patent Application Laid-Open No. 11-204297 (claim 1, paragraph [0011] and others) and Japanese Patent Application Laid-Open No. 2000-40695 (paragraphs [0010], [0013] and others) disclose that a method, in which a magnetic field is continuously applied to the whole area between electrodes during plasma process, is used.

### SUMMARY

According to an aspect of the present invention, there is provided a manufacturing method for semiconductor device including: placing a wafer on a lower electrode disposed in a reaction chamber; introducing process gas into the reaction chamber; applying a magnetic field at a position spaced from a surface of the wafer to be processed; generating plasma by applying a high-frequency voltage between the lower electrode and an upper electrode disposed to face the lower electrode; removing the magnetic field after the plasma is stabilized; and plasma-processing the wafer.

According to an aspect of the present invention, there is provided a manufacturing apparatus for semiconductor device for plasma-processing a wafer including: a reaction chamber, in which the wafer is plasma-processed; an upper electrode and a lower electrode disposed in the reaction chamber, the upper electrode having a process gas inlet and a lower electrode being disposed to face the upper electrode and having a placement surface, on which a wafer is placed; a high-frequency power supply for applying a high-frequency voltage between the upper electrode and the lower electrode; a magnetic field applying unit for applying a magnetic field at a position spaced from a surface of the wafer to be processed and a position closer to the upper electrode between the upper electrode and the lower electrode; and a magnetic field control unit for controlling timing to apply a magnetic field applied by the magnetic field applying unit.

### BRIEF DESCRIPTION OF THE DRAWINGS

FIG. 1 is a sectional view of a plasma processing apparatus according to an embodiment of the present invention;

FIG. 2 is a schematic view illustrating a condition where plasma is non-uniform according to an embodiment of the present invention;

FIG. 3 is a schematic view illustrating a condition where plasma is non-uniform according to an embodiment of the present invention;

FIG. 4 is a schematic view illustrating a condition where plasma is stabilized by a magnetic field according to an embodiment of the present invention; and

FIG. 5 is a schematic view illustrating a condition where plasma is stabilized according to an embodiment of the present invention.

### DETAILED DESCRIPTION

Reference will now be made in detail to the present embodiment of the invention, an example of which is illustrated in the accompanying drawings. Wherever possible, the same reference numbers will be used throughout the drawing to refer to the same or like parts.

### First Embodiment

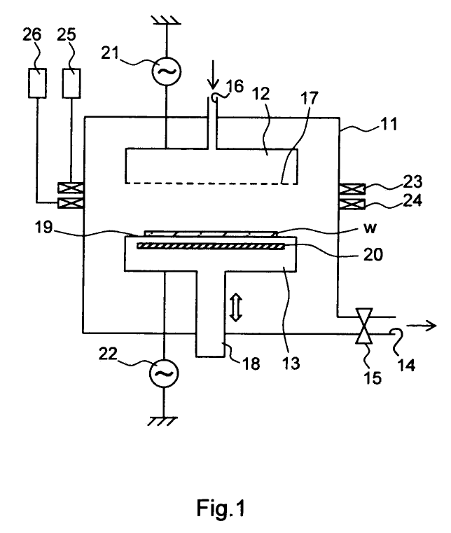

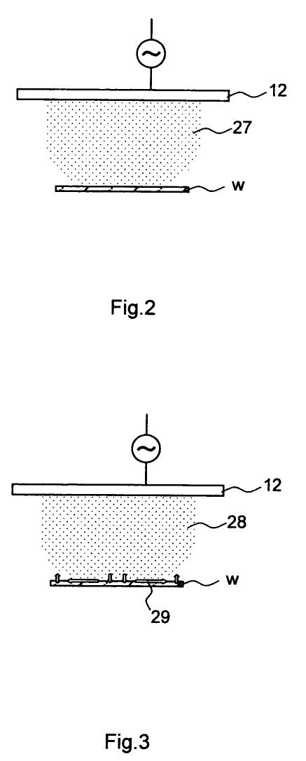

FIG. 1 is a sectional view of a plasma processing apparatus as a manufacturing apparatus for semiconductor device according to the present embodiment. A reaction chamber 11 for plasma-process of a wafer w is provided with an upper electrode 12 and a lower electrode 13 disposed to face the upper electrode. The reaction chamber 11 is airtight and has an exhaust port 14 connected with a vacuum pump or the like capable of exhausting in a vacuum state. The exhaust port 14 is connected with an exhaust regulating valve 15, whereby inside of the reaction chamber 11 can be controlled at a predetermined pressure.

The upper electrode 12 is a disc-shaped shower electrode supported on an upper lid of the reaction chamber 11. The upper electrode 12 has: a process gas inlet 16 for introducing process gas of a predetermined gas type and flow rate; and tiny holes 17, which is connected to the process gas inlet 16 and penetrates through to the bottom to allow spraying process gas over a surface of the wafer w to be processed.

The lower electrode 13 is supported by a support pillar 18 from the lower portion of the reaction chamber 11 and the lower electrode 13 has a susceptor 19 on which a wafer w is placed. The susceptor 19 incorporates a cooling pipe (not illustrated) to circulate coolant and a heater 20 such as a resistive heater so as to keep a susceptor temperature constant. The support pillar 18 is provided with a vertical drive unit (not illustrated). The vertical drive unit lifts up and down the susceptor 19 so as to change a distance between the upper electrode 12 and the lower electrode 13.

High-frequency power supplies 21, 22 for applying a high-frequency voltage between the upper electrode 12 and the lower electrode 13 are connected to the upper electrode 12 and the lower electrode 13, respectively. In a process with no bias applied, the lower electrode 13 is grounded.

On the external side faces of the reaction chamber 11, there are provided two-stage magnets 23, 24 for applying a magnetic field, which is parallel to a surface to be processed of the wafer w, spaced from the surface of the wafer w, and closer to the upper electrode 12 between the upper electrode 12 and the lower electrode 13. Magnets capable of generating a horizontal magnetic field, such as a dipole ring magnet, may be used as the electromagnets 23, 24. The electromagnets 23, 24 are connected to electromagnet power supplies 25, 26, respectively. The electromagnet power supplies 25, 26 are provided with a magnetic field control unit (not illustrated) capable of controlling timing and strength to apply the magnetic field in accordance with timing to apply high-frequency voltage.

Using such a plasma processing apparatus, the plasma process is performed as follows, for example. Description will be made on a case in which the present embodiment is applied to a process of: forming Cu damascene interconnect by the plating method or the like; and depositing a low dielectric constant film having SiCNH composition (hereinafter referred to as “SiCNH film”) by plasma CVD method on an Si wafer having a surface flattened by the CMP (Chemical Mechanical Polishing) method.

In film formation, plasma etching process is performed as a preprocess of the wafer. This is performed in order to prevent degradation of interconnect reliability by removing oxide (CuOx) existing on a surface of damascene interconnect.

First, insides of a transfer chamber (not illustrated) and the reaction chamber 11 are vacuumed through an exhaust port 14. The wafer w is transferred to the reaction chamber 11 from a transfer chamber (not illustrated) and is placed on the susceptor 19. The wafer w is heated to a temperature allowing plasma process, 350° C., for example, by the heater 20. On the other hand, process gas is flow-controlled in a manner that NH₃ gas, which is etching gas for removing oxide on Cu damascene interconnect surface, is 500 sccm and N₂ gas for diluting the NH₃ gas is 10,000 sccm, for example. The flow-controlled process gas is introduced through the process gas inlet 16 and is sprayed onto the heated wafer w through the tiny holes 17.

At this time, the pressure inside the reaction chamber 11 is automatically adjusted to be 5 Torr by the exhaust regulating valve 15. The support pillar 18 lifts up and down the susceptor 19 to set a distance between the upper electrode 12 and the lower electrode 13 to 30 mm, for example.

In such condition, a high-frequency voltage of 13.56 MHz, for example, is applied to the upper electrode 12 by a high-frequency power supply 21 and the lower electrode 13 is grounded to discharge at 500 W. When high frequency is applied, especially when discharge starts (plasma ignite), plasma is formed in gas flow and therefore volumetric expansion occurs due to dissociation of molecule gas, and then the pressure in the reaction chamber temporarily increases.

At this time, to offset the pressure increase, exhaust is automatically adjusted by the exhaust regulating valve 15. However, the pressure fluctuates and thus plasma 27 becomes unstable and then the plasma on the wafer w becomes non-uniform. By performing Plasma process under such a condition, a charge-up 29 is formed on the wafer w due to the non-uniform plasma 28 as illustrated in FIG. 3 and thus plasma damage occurs. Further, because the plasma is not uniform on the wafer w, non-uniform charge-up occurs. The non-uniform charge-up further accelerates occurrence of plasma damage.

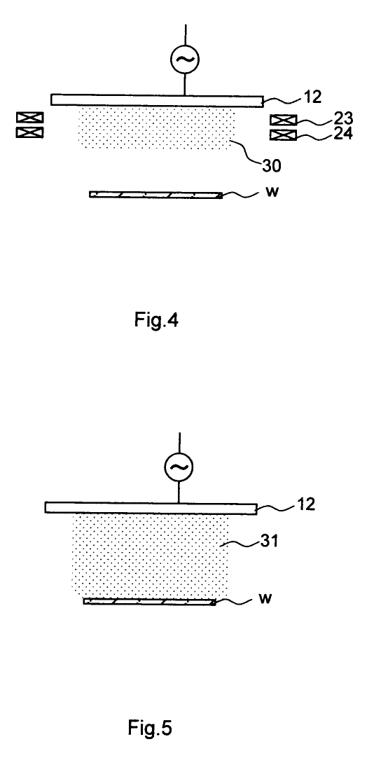

For example, 5 seconds before discharge, the electromagnet power supplies 25, 26 apply electric current to the electromagnets 23, 24, respectively to generate a magnetic field of 200 Gauss by the upper electromagnet 23 and 100 Gauss by the lower electromagnet 24. Under the condition where a magnetic field is generated as such, discharge is started so as to concentrate plasma 30 toward the upper electrode 12 as illustrated in a schematic view of FIG. 4 upon starting of the discharge.

As described above, discharge is started under a condition where a magnetic field is generated and electric current flowing from the electromagnet power supplies 25, 26 to the electromagnets 23, 24 respectively is stopped so as to remove the magnetic fields when the plasma becomes stable toward the upper electrode 12 after a lapse of 3 seconds, for example. Upon removal of the magnetic fields, the wafer w is uniformly exposed to plasma 31, which has been plasma 30 concentrated toward the upper electrode 12, as illustrated in a schematic view of FIG. 5. At this time, by removing the magnetic fields in stages such as to be ½ and ⅓, the wafer w can be exposed to the plasma 31 more uniformly. Specifically, the electromagnet 23 may be changed to generate 200 Gauss, 100 Gauss and 50 Gauss every second and the electromagnet 24 may be changed to generate 100 Gauss, 50 Gauss and 25 Gauss every second, for example.

After removal of the magnetic fields, plasma process is performed on the wafer w for 30 seconds, for example, so that CuOx on a Cu damascene interconnect is removed. Similarly, the electromagnet power supplies 25, 26 apply electric current to the electromagnets 23, 24, respectively to generate a magnetic field of 200 Gauss by the upper electromagnet 23 and a magnetic field of 100 Gauss by the lower electromagnet 24. Under the conditions where a magnetic field is generated as such, a high-frequency voltage is stopped so as to stop discharge. Upon discharge stop, dissociation of gas stops, and then pressure temporarily decreases, whereby a pressure fluctuation occurs. The pressure fluctuates and thus the plasma becomes unstable, however, upon discharge stop, the plasma is concentrated toward the upper electrode 12.

Electric current flowing from the electromagnet power supplies 25, 26 to the electromagnets 23, 24, respectively is stopped so as to remove the magnetic fields. After removal of the magnetic fields, introducing NH₃ gas and N₂ gas through the process gas inlet 16 is stopped. The exhaust regulating valve 15 is opened to evacuate through the exhaust port 14, thus removing gas in the reaction chamber 11.

An SiCNH film is formed by plasma CVD, on the Cu damascene interconnect purified by removing CuOx. Then film formation gas, instead of etching gas, is introduced into the reaction chamber 11 through the process gas inlet 16. The process gas is flow-controlled in a manner that flow rate of TMS (trimethylsilane) gas is 400 sccm, that of NH₃ is 800 sccm, and that of He gas is 200 sccm, for example. The flow-controlled process gas is introduced through the process gas inlet 16 and is sprayed onto the wafer w through the tiny holes 17. At this time, the wafer w is heated to 350° C. by the heater 20.

Similarly to the case where CuOx is removed, the pressure inside the reaction chamber 11 is automatically adjusted to be 5 Torr by the exhaust regulating valve 15. The support pillar 18 lifts up and down the susceptor 19 to set a distance between the upper electrode 12 and the lower electrode 13 to 30 mm.

A high-frequency voltage of 13.56 MHz, for example, is applied to the upper electrode 12 by the high-frequency power supply 21, and the lower electrode 13 is grounded to discharge at 1,000 W this time. Similarly to the case where CuOx is removed, for example, 5 seconds before discharge, the electromagnet power supplies 25, 26 apply electric current to the electromagnets 23, 24, respectively to generate a magnetic field of 200 Gauss by the upper electromagnet 23 and 100 Gauss by the lower electromagnet 24. Under the conditions where a magnetic field is generated as such, discharge is started so as to concentrate plasma toward the upper electrode 12 upon starting of the discharge.

As described above, discharge is started under the conditions where a magnetic field is generated. Then, in order to suppress film quality change of deposited film (SiCNH film) to be formed, electric current from the electromagnet power supplies 25, 26 to the electromagnets 23, 24 respectively is stopped so as to remove the magnetic field when the plasma becomes stable toward the upper electrode 12 after a lapse of 1 second, for example. Similarly to the case where CuOx is removed, a wafer w is uniformly exposed to the plasma, which has been concentrated toward the upper electrode 12, upon removal of the magnetic field.

After removal of the magnetic fields, plasma process is performed on the wafer w for 20 seconds, for example, so that an SiCNH film of 50 nm, for example, is formed. Similarly, the electromagnet power supplies 25, 26 apply electric current to the electromagnets 23, 24, respectively to generate a magnetic field of 200 Gauss by the upper electromagnet 23 and 100 Gauss by the lower electromagnet 24. Under the conditions where a magnetic field is generated as such, a high-frequency voltage is stopped so as to stop discharge. Upon discharge stop, dissociation of gas stops, then pressure temporarily decreases and a pressure fluctuation occurs. The pressure fluctuates and thus the plasma becomes unstable, however, the plasma is concentrated toward the upper electrode 12 upon discharge stop.

Electric current from the electromagnet power supplies 25, 26 to the electromagnets 23, 24, respectively is stopped so as to remove the magnetic fields. After removal of the magnetic fields, introducing TMS (trimethylsilane) gas, NH₃ gas and He gas through the process gas inlet 16 is stopped. The exhaust regulating valve 15 is opened to evacuate through the exhaust port 14, thus removing gas in the reaction chamber 11.

Accordingly, plasma process can be performed without forming non-uniform plasma on a wafer when discharge starts and discharge ends in the removal of CuOx by plasma etching and in formation of an SiCNH film by plasma CVD. Particularly, the embodiment is more effective when discharge starts because an origin of plasma discharge exists and non-uniform plasma tends to occur.

In the present embodiment, a frequency of the high-frequency power supply is 13.56 MHz, however, higher frequency (e.g. 60 MHz) may be used recently in order to improve film quality. To the lower electrode, high frequency may be applied as bias control. When higher frequency is used or bias is applied, non-uniform plasma tends to occur and then plasma damage tends to occur. Even in conditions favorable for plasma damage as described above and even if an applied frequency is increased to improve film quality, device damage can be suppressed according to the present embodiment. Accordingly, performance degradation of a transistor to be fabricated and product yield degradation can be suppressed.

The film quality of SiCNH film formed according to the present embodiment, which may be used as a low-dielectric-constant film, for example, can be improved without causing device damage. Accordingly, device performance can be improved and as an example, capacity between interconnects can be reduced. Further, the SiCNH film functions as a Cu block film used in forming Cu damascene interconnect and functions as an etching stopper film in process and therefore film quality improvement provides stabilized process and yield improvement.

After the plasma is stabilized, electric current from the electromagnet power supplies 25, 26 to the electromagnets 23, 24 respectively is stopped so as to remove the magnetic fields. Accordingly, plasma behavior is not interfered by the magnetic field. Hence, an influence of the magnetic field on a main process can be suppressed. If the magnetic fields are continuously applied, a CVD film is formed around the upper electrode, not on a wafer w, which causes dust generation. In addition, if magnetic fields are continuously applied with the direction of a magnetic field kept constant during film formation, a plasma high-density portion is generated depending upon the magnetic field direction and in-plane dependency of film quality of formed film become significant. Accordingly, removing the magnetic fields after plasma is stabilized enables uniform quality and high yield.

Furthermore, for the plasma process apparatus, arcing caused by non-uniform plasma can be suppressed. Therefore, it is possible to prevent degradation of the plasma process apparatus; reduce maintenance cost; and achieve high productivity.

### Second Embodiment

In the present embodiment, an SiCNH film is formed using the plasma process apparatus illustrated in FIG. 1 similarly to the First Embodiment. However, the present embodiment is different in that film quality, specifically, film composition is changed during film formation.

An SiCNH film is formed, by plasma CVD, on the Cu damascene interconnect purified by removing CuOx, similarly to the First Embodiment. For example, the process gas, which is flow-controlled in a manner that flow rate of TMS (trimethylsilane) gas is 400 sccm, that of NH₃ is 800 sccm, and that of He gas is 2000 sccm, is introduced through the process gas inlet 16 and sprayed onto a wafer w through the tiny hole 17 similarly to the First Embodiment.

At this time, similarly to the First Embodiment, the pressure inside the reaction chamber 11 is automatically adjusted to be 5 Torr and a distance between the upper electrode 12 and the lower electrode 13 is set to 30 mm, for example.

Under such conditions, similarly to the First Embodiment, a high-frequency voltage of 13.56 MHz, for example, is applied to the upper electrode 12 by the high-frequency power supply 21, and the lower electrode 13 is grounded to discharge at 1,000 W. In addition, for example, 5 seconds before discharge, the electromagnet power supplies 25, 26 apply electric current to the electromagnets 23, 24, respectively, to generate a magnetic field of 200 Gauss by the upper electromagnet 23 and 100 Gauss by the lower electromagnet 24. Under the conditions where a magnetic field is generated as such, discharge is started so as to concentrate plasma toward the upper electrode 12 upon starting of the discharge.

As described above, discharge is started under the conditions where a magnetic field is generated. Then, in order to suppress film quality change of deposited film (SiCNH film) to be formed, electric current from the electromagnet power supplies 25, 26 to the electromagnets 23, 24 is stopped to remove the magnetic field when the plasma becomes stable toward the upper electrode 12 after the lapse of one second, for example. Upon removal of the magnetic fields, the wafer w is uniformly exposed to the plasma, which has been concentrated toward the upper electrode 12 similarly to the First Embodiment.

After removal of the magnetic fields, plasma process is performed on the wafer w for 20 seconds, for example, so that an SiSNH film of 50 nm, for example, is formed.

The electromagnet power supplies 25, 26 apply electric current to the electromagnets 23, 24, respectively, to generate a magnetic field of 200 Gauss by the upper electromagnet 23 and 100 Gauss by the lower electromagnet 24. Under the conditions where a magnetic field is generated as such, the process gas is fluctuated. The process gas, which is flow-controlled in a manner that flow rate of DMPS (dimethyl-phenylsilane) gas is 1,000 mg/min and that of He gas is 2,000 sccm, for example, is introduced through the process gas inlet 16 and sprayed onto a wafer w through the tiny hole 17.

At this time, similarly, the pressure inside the reaction chamber 11 is automatically adjusted to be 5 Torr and set a distance between the upper electrode 12 and the lower electrode 13 to 20 mm, for example.

Under such conditions, a high-frequency voltage of 13.56 MHz, for example, is applied to the upper electrode 12 by the high-frequency power supply 21, and the lower electrode 13 is grounded to discharge at 500 W this time. When the plasma discharge becomes stable after the lapse of about one second, electric current from the electromagnet power supplies 25, 26 to the electromagnets 23, 24 is stopped to remove the magnetic fields.

After removal of the magnetic fields, plasma process is performed on the wafer w for 20 seconds, for example, so that an SiCH film of 50 nm having different film quality from an SiCNH film at the lower layer is formed, for example. Similarly, the electromagnet power supplies 25, 26 apply electric current to the electromagnets 23, 24, respectively to generate a magnetic field of 200 Gauss by the upper electromagnet 23 and a magnetic field of 100 Gauss by the lower electromagnet 24. Under the conditions where a magnetic field is generated, a high-frequency voltage is stopped so as to stop discharge.

After the electric current flowing from the electromagnet power supplies 25, 26 to the electromagnets 23, 24 is stopped to remove the magnetic fields, introducing the gas through the process gas inlet 16 is stopped. The exhaust regulating valve 15 is opened to evacuate through the exhaust port 14, thus removing gas in the reaction chamber 11. Hence, a laminated structure of SiCNH/SiCH films is formed.

Even if film quality fluctuates during film formation and the condition of the process gas varies, thereby causing non-uniform plasma, plasma process can be performed without forming non-uniform plasma on a wafer according to the present embodiment, similarly to the First Embodiment. In addition to the effect, the present embodiment provides the same effects as the First Embodiment.

Furthermore, discharge starts in the conditions where a magnetic field is generated and the magnetic filed is removed in the conditions where plasma is stable, thus inhibiting a film quality fluctuation in a deposited film (SICH film) to be newly formed.

In the present embodiment, the laminated structure of SiCNH/SiCH films is formed. Generally, the SICH film has lower Cu block performance and etching stopper performance than the SiCNH film, however the dielectric constant of which can be lowered. Accordingly, such laminated structure of SiCNH/SiCH films is preferable in forming an insulating film for multi-layer wiring. Since such laminated structure of SiCNH/SiCH films can be formed without any plasma damage, dielectric constant of an interlayer insulation film can be further lowered.

In the above-described embodiments, timing to apply a magnetic field and magnetic field intensity is set to be predetermined values, but are not limited thereto. A direction of applied magnetic field can be optimized as needed. In addition, the position to apply the magnetic field is fixed, but may be movable. For example, based on evaluation of damage such as deterioration and destruction of an oxidized film of a wafer processed under predetermined conditions, these conditions can be optimized as needed.

In the above-described embodiments, a dipole ring magnet is used as a means for applying a magnetic field, but a means for applying a magnetic field is not particularly limited thereto, and may be of a ring shape or may be composed of a plurality of electromagnets. The magnetic field may be applied at any position spaced from a surface of a wafer w to be processed. Preferably, the magnetic field is applied between the upper electrode and the lower electrode. More preferably, the magnetic field is applied closer to the upper electrode than a middle position between the upper and lower electrodes (a position of ½ distance between the upper and lower electrodes). After the magnetic field is applied, the intensity of the magnetic field may be varied. For example, in removing the magnetic field, the intensity of the magnetic field may be gradually decreased.

Preferably, the direction of magnetic field is parallel to a surface of a wafer w to be processed, but the magnetic field is not necessarily formed in one axial direction. Even if the direction of a magnetic field varies during the process, the same effects can be provided.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A manufacturing method for semiconductor device comprising:
placing a wafer on a lower electrode disposed in a reaction chamber;
introducing process gas into the reaction chamber;
applying a magnetic field at a position spaced from a surface of the wafer to be processed;
generating plasma by applying a high-frequency voltage between the lower electrode and an upper electrode disposed to face the lower electrode;
removing the magnetic field after the plasma is stabilized; and
plasma-processing the wafer.

2. The manufacturing method according to claim 1, further comprising:
applying the magnetic field after the plasma-processing the wafer; and
removing the magnetic field after stopping the application of the high-frequency voltage.

3. The manufacturing method according to claim 1, wherein the magnetic field is applied between the upper electrode and the lower electrode.

4. The manufacturing method according to claim 3, wherein the magnetic field is applied at a position closer to the upper electrode than a middle position between the upper electrode and the lower electrode.

5. The manufacturing method according to claim 1, wherein the process gas includes etching gas.

6. The manufacturing method according to claim 5, wherein Cu damascene interconnect is formed on the wafer and oxide on a surface of the Cu damascene interconnect is removed by the etching gas.

7. The manufacturing method according to claim 1, wherein the process gas includes film formation gas.

8. The manufacturing method according to claim 7, further comprising forming an interlayer insulation film on the wafer by the film formation gas.

9. The manufacturing method according to claim 8, wherein the interlayer insulation film is an SiCNH film or an SiCH film.

10. The manufacturing method according to claim 1, further comprising:
applying the magnetic field;
changing a process condition; and
removing the magnetic field.

11. The manufacturing method according to claim 10, wherein the process condition is changed by changing type of the process gas.

12. The manufacturing method according to claim 11, wherein the changing type of the process gas is changing from etching gas to film formation gas.

13. The manufacturing method according to claim 11, wherein the process gas is film formation gas.

14. The manufacturing method according to claim 13, further comprising laminating different types of interlayer insulation films on the wafer.

15. The manufacturing method according to claim 14, wherein an SiCNH film and an SICH film are laminated as the interlayer insulation films.

16. The manufacturing method according to claim 1, further comprising changing the intensity or orientation of the magnetic field after the applying the magnetic field.

17. A manufacturing apparatus for semiconductor device for plasma-processing a wafer comprising:
a reaction chamber for plasma-processing the wafer;
an upper electrode and a lower electrode disposed in the reaction chamber, the lower electrode being disposed to face the upper electrode, the lower electrode having a placement surface to place the wafer;
a high-frequency power supply for applying a high-frequency voltage between the upper electrode and the lower electrode;
a magnetic field applying unit for applying a magnetic field at a position spaced from a surface of the wafer to be processed and a position closer to the upper electrode side between the upper electrode and the lower electrode; and
a magnetic field control unit for controlling timing to apply a magnetic field applied by the magnetic field applying unit.

18. The manufacturing apparatus according to claim 17, wherein the timing to apply a magnetic field is controlled in accordance with a timing to apply the high-frequency voltage.

19. The manufacturing apparatus according to claim 17, wherein the upper electrode has a process gas inlet.

20. The manufacturing apparatus according to claim 17, wherein a lower electrode is vertically movable.
